(19) United States
(12) Patent Application Publication
(10) Pub. No.: US 2009/0170305 A1
(43) Pub. Date: Jul. 2, 2009

(54) METHOD FOR IMPROVING ELECTROMIGRATION LIFETIME FOR CU INTERCONNECT SYSTEMS

(75) Inventors: Jeffrey A. West, Dallas, TX (US); Richard A. Faust, Dallas, TX (US); Srinivasa Raghavan, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/047,485

(22) Filed: Mar. 13, 2008

Related U.S. Application Data
(60) Provisional application No. 61/018,041, filed on Dec. 31, 2007.

(51) Int. Cl. H01L 21/4763

(52) U.S. Cl. 438/618; 257/E21.58

(57) ABSTRACT

A method for forming a single damascene and/or dual damascene interconnect structure, comprising: performing front end processing, depositing copper, annealing the copper, performing CMP planarization, performing a post copper CMP clean process, performing a BTA rinse, performing IPA drying process, performing doping during thermal ramp up and performing remaining back end processing.

### REFERENCE TO RELATED APPLICATION

This application claims priority to and the benefit of U.S. Provisional Application Ser. No. 61/018,041 which was filed Dec. 31, 2007, entitled METHOD FOR IMPROVING ELECTROMIGRATION LIFETIME FOR CU INTERCONNECT SYSTEMS, the entirety of which is hereby incorporated by reference as if fully set forth herein.

### FIELD OF THE INVENTION

This invention relates generally to semiconductor processing, and more particularly to a method and process for improving electromigration lifetime for copper interconnect systems and/or devices.

### BACKGROUND OF THE INVENTION

Integrated circuits (ICs) are formed on semiconductor substrates using different processing techniques, known in the art, to produce transistors, interconnection elements, and the like. Interconnection requirements have become more demanding with the requirements for higher density. In order to electrically connect transistors on the semiconductor substrate, conductive vias, trenches and interconnects are formed in the dielectric materials as part of the integrated circuit. These vias, trenches and electrical interconnections combine electrical signals and power between transistors, internal circuits of the IC, and circuits external to the integrated circuit, for example.

The semiconductor industry is constantly working to improve the quality, reliability and throughput of integrated circuits based in part upon consumer demand for higher quality devices. Factors, such as feature critical dimensions, doping levels, contact resistance, particle contamination, interlayer dielectrics, conductive patterns, etc., all may potentially affect the end performance of the electrical device. Copper is increasingly becoming the material of choice for forming conductive interconnections on integrated circuit devices. This is due, in large part, to the superior electrical characteristics of copper as compared to other materials, e.g., aluminum, previously used to form such interconnections; it is relatively inexpensive and easy to process.

Copper is not readily etched by chemical processes and thus fabrication processes such as single damascene and dual damascene have been utilized to create copper conductive interconnections. In general, such methods involve forming a patterned layer of insulating material having multiple openings, such as trench interconnect lines or interconnect vias to connect the different layers, formed therein, forming a barrier metal layer above the patterned insulating layer and in the openings, forming a copper seed layer above the barrier metal layer, performing an electroplating process to deposit a bulk copper layer above the copper seed layer and, thereafter, performing one or more chemical mechanical polishing processes to remove the excess copper and barrier material from above the patterned insulating layer.

Damascene interconnection processes for semiconductor devices are replacing conventional deposition and etch processes. Traditionally, metal films have been deposited and patterned using photolithography to pattern metal interconnects within a semiconductor substrate. As conductive lines are patterned closer and closer together and as interconnections shrink, it becomes more and more difficult to accurately pattern the conductive lines and form the conductive interconnects using the conventional layered deposition and patterning processes that do not suffer in some way from electrical or mechanical problems. Semiconductor devices comprising five or more levels of metallization are becoming more and more commonplace as semiconductors push minimization geometries in the sub-half-micron region.

Increased performance of microprocessor devices demands faster electronic speeds within the semiconductor circuitry. The control speeds within the circuitry is inversely dependent on the resistance and capacitance of the semiconductor interconnections. With decreased feature sizes, trench widths, added complexity, etc., control speed is less dependent on the semiconductor device and more dependent on the interconnection patterns and the interconnection integrity.

For example, dielectric etch stop layering techniques are well known by those of ordinary skill in the art. In one process a special plasma treatment is carried out before the etch stop layer (e.g., silicon nitride) deposition since copper is not self passivating as is aluminum to form an oxide (e.g., aluminum oxide, and the like) that if not cleaned off can result in poor adhesion between the copper and the etch stop layer silicon nitride, for example. With weak adhesion, Cu atoms can diffuse along the interface between copper and silicon nitride to significantly degrade electromigration lifetime, for example.

The copper-dielectric interface has been extensively studied and characterized in the literature. However, the following manufacturing issues have been observed, e.g., interface adhesion failures, delamination, Cu hillock defects, metal sheet resistance variation, voltage ramped dielectric breakdown (VRDB) leakage, time dependent dielectric breakdown (TDDB) leakage, and pad peeling.

Therefore, a method and process for damascene processing is desired that allows for increased reliability of the IC devices and an improved electromigration lifetime. The present invention is directed to overcoming, or at least reducing the effects of, one or more of the problems set forth above.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Its sole purpose is to present some concepts of the invention in a simplified form as a prelude to the more detailed description that is presented later.

However, as will be apparent to those skilled in the art, the present invention may be practiced without these specific details or by using alternate acts, elements or processes. In other instances well-known processes, procedures and components have not been described in detail so as not to unnecessarily obscure aspects of the present invention. The methods may be employed on recessed trenches in single or dual damascene devices.

The present invention according to one or more aspects of the invention pertains to a method for forming a single damascene and/or dual damascene, via and interconnect structure, comprising: performing front end processing, depositing copper, annealing the copper, performing CMP planarization, performing a post copper CMP clean process, performing a BTA (benzotriazole) rinse, performing IPA drying process, performing doping during thermal ramp up and performing remaining back end processing.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1A is a cross sectional diagram illustrating a damascene device formed according to at least one aspect of the present invention;

FIG. 1B is another cross sectional diagram illustrating a damascene device formed according to at least one aspect of the present invention;

FIG. 1C is yet another cross sectional diagram illustrating a damascene device formed according to at least one aspect of the present invention;

FIG. 2A is a flow chart diagram illustrating a method of forming a dual damascene structure according to at least one aspect of the present invention; and

FIG. 2B is a flow chart diagram illustrating a continuation of the device formed in FIG. 2A, according to at least one aspect of the present invention.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present invention. It may be evident, however, to one skilled in the art that one or more aspects of the present invention may be practiced with a lesser degree of these specific details. In other instances, well-known structures and devices are shown in block diagram or other form in order to facilitate describing one or more aspects of the present invention.

In accordance with the present invention, a method is provided for forming a dual damascene structure, for example, for an integrated circuit (IC) interconnect. In one aspect of the present invention, the method improves electromigration lifetime of copper interconnect systems, described supra. The advantages in the present invention are achieved by performing a post-Cu CMP ex-situ citric/BTA/IPA hood clean. Typical processing eliminates the post-Cu CMP ex-situ clean; however the inventors recognized the benefits of lower defectivity and improved reliability when using the hood clean process along with BTA exposure.

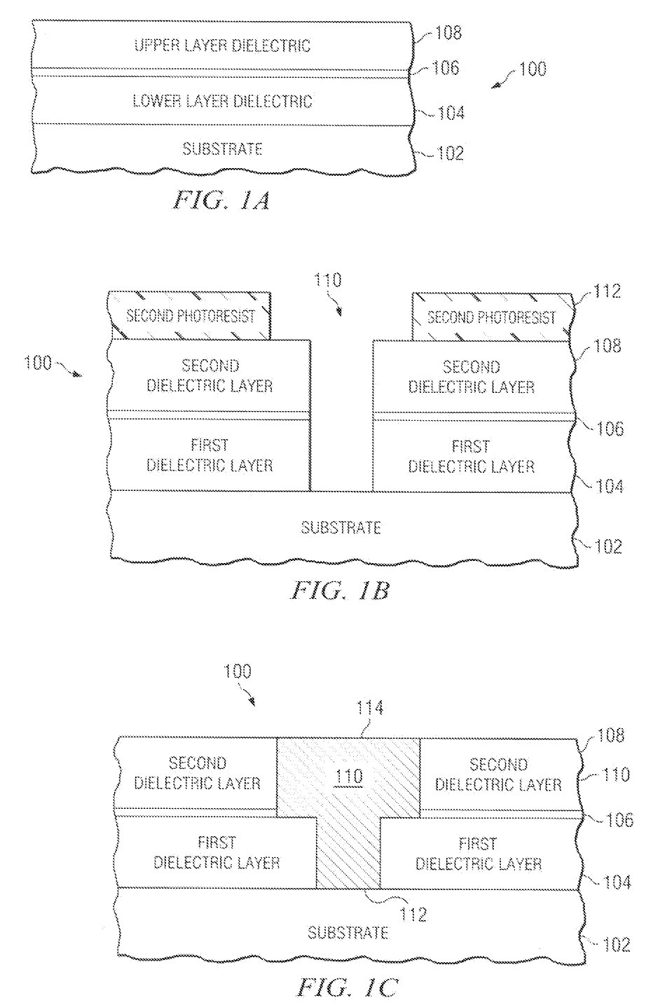

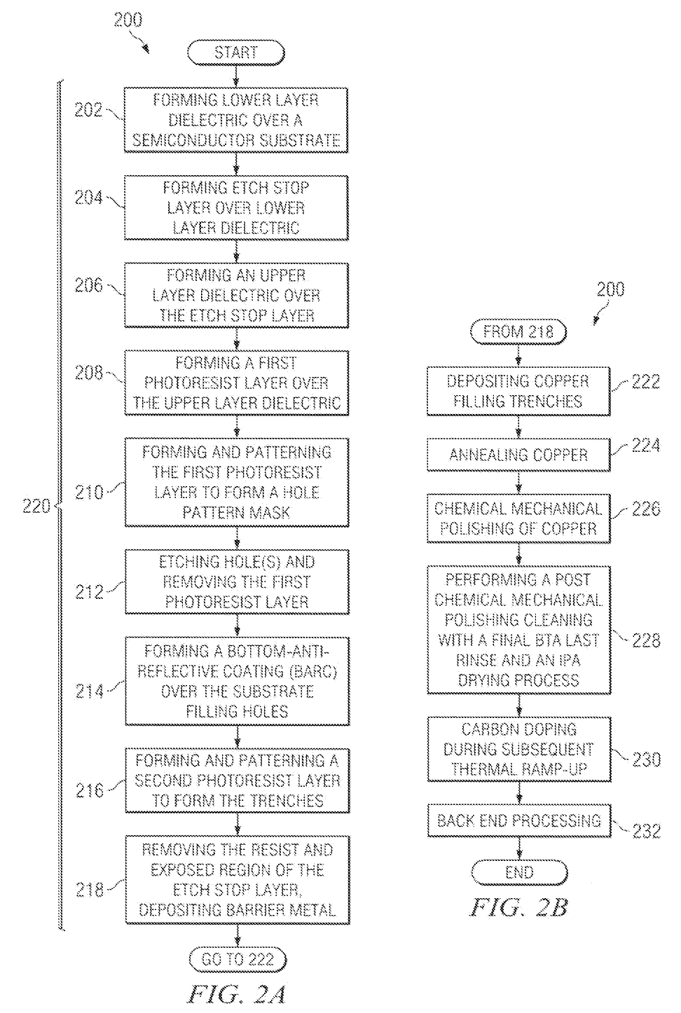

The invention will now be described with reference to FIGS. 1A, 1B, 1C, 2A and 2B. FIG. 1A according to at least one aspect of the present invention represents a dual damascene device that is made according to the method illustrated in FIGS. 2A and 2B. The formation of damascene structures, for example, is disclosed in commonly assigned patents; U.S. Pat. No. 6,605,540 and U.S. Pat. No. 6,358,849, as well as U.S. Pat. No. 6,042,999. It will be apparent to those of ordinary skill in the art that the benefits of the invention can be applied to other structures where a dual damascene process is utilized.

The benefit of copper is that it offers lower resistivity than the historically dominant interconnect material, aluminum leading to its use in forming the metal interconnects in integrated circuits. Using a lower resistivity interconnect material like copper decreases the interconnection RC delay, that in turn increases the integrated circuit speed.

Although the present invention is initially described in the context of forming conductive interconnections, those skilled in the art, after reading the entirety of the present application, will understand that the methods of the present invention may be employed to form conductive interconnections at any level of an integrated circuit device using a variety of techniques, such as single or dual damascene integration techniques.

In at least one embodiment of the present invention, the method begins at 202 (FIG. 2A), a lower layer dielectric 104 (LLD) can be formed over a portion of a substrate 102 as shown in FIG. 1A, illustrating a partially formed copper interconnect structure 100. The substrate 102 can be silicon, for example, formed with a variety of electronic devices (not shown) in the substrate 102 such as copper conductive structures, transistors, diodes, etc., typically part of an IC. The devices are formed in the substrate 102 or in segments of the copper metal layers, for example therein and will not be described in detail in the present invention to obscure the following description. In one example, the transistor, for example, is comprised of source/drain regions and a patterned layer of insulating material having a plurality of conductive trenches or contacts formed therein. As will be recognized by those skilled in the art, the conductive contacts provide electrical contact to the source/drain regions of the transistor. The materials used to form the components of the transistor, as well as the methods of making such components, are generally well-known to those skilled in the art and will not be described herein in any greater detail.

In FIG. 2A at 204 an etch stop layer 106 may be formed over the lower layer dielectric 104 and can be a thin conformal material that can comprise silicon nitride (SiN) materials, silicon oxide materials, silicon oxynitride (Si₂N₂O), silicon carbo-nitride (SiCN), or any suitable material known by those of skill in the art. At 206 (FIG. 2A) an upper layer dielectric 108 (ULD) is formed over the etch stop layer 106 (FIG. 1A). In an embodiment of the present invention the lower layer dielectric 104 can comprise a variety of suitable materials, e.g., florosilicate glass (FSG), organosilicate glass (OSG), ONO (oxide/nitride/oxide), dielectric materials mentioned supra and other suitable materials known to those of skill in the art. The terms LLD and ULD will be used in this invention to distinguish the lower and upper layer dielectric layers, respectively, and the term “hole” will refer to either a contact hole or a via hole.

Subsequent to the formation of the upper layer dielectric 108, a first photoresist layer (not shown) at 208 (FIG. 2A) may be formed and patterned with a mask (not shown) having a hole pattern at 210 over the ULD 108. The first photoresist layer can be formed according to methods that are well known by those of skill in the art, for example, via a spin-coating process. The first photoresist layer is patterned by selectively exposing the photoresist to radiation followed by development thereof according to photolithography techniques known by those of skill in the art. At 212 the patterned holes 110 (FIG. 1B) are etched through the ULD 108, the etch stop layer 106 and the LLD 104 exposing a portion of the substructure of the substrate, for example. The full vias are formed in a first etching process at 212. The holes 110, for example, extend down to a lower level metal that is connected through contacts to selected source/drains, areas on gate level interconnects, selected bitlines and the like. The first photoresist layer (not shown) can be subsequently removed at 212 and a via protection layer can be applied at 214, as well, utilizing methods that are well known by those of skill in the art.

At 216 (FIG. 2A), a second photoresist layer 112 (FIG. 1A) can be formed and patterned which will be used to define the trenches. Using the patterned photoresist film as an etch mask, the ULD 108 is selectively removed using etching techniques that are well known by those of skill in the art. During the etching process of the dielectric layers 108 and 104 the photoresist layers will protect regions of the ULD not intended to be etched, or alternatively, hard masks known by those of skill in the art may be used to achieve similar ULD protection and all such masking schemes are contemplated within the present invention.

During the formation of the trench in the upper layer dielectric 108, an optional bottom antireflective coating (BARC) (not shown) can be used as a protective layer. The formation of BARC coatings, ARC layers or other types of protective layers is well known by those of skill in the art.

Following the formation of both vias and trenches, the exposed region of the first etch stop layer 106 is removed at 218 (FIG. 2A). Any ARC above the ULD and any previous etch stop layer directly below the LLD, exposed by the via etch; can also be removed during this step. The acts referred to in FIG. 2A, namely 202, 204, 206, 208, 210, 212, 214, 216 and 218 can arbitrarily be referred to as front end processing 220 (see bracketed processes in FIG. 2A). It should be appreciated that the term “front end processing” is totally arbitrary and could include additional processes or delete some of the acts shown. There are numerous methods and techniques for forming damascene type structures and only one such method is mentioned herein.

The barrier metal deposition at 218 is followed by copper deposition (e.g., PVD deposition of seed copper and electroplating of the remaining copper) at 222 (FIG. 2B), annealing of the copper at 224 (FIG. 2B), and chemical mechanical polishing (CMP) process at 226 (FIG. 2B) which results in the copper layer 114 as shown in FIG. 1C. The techniques and methods used to form the copper layer 116, prior to CMP, using electroplating and other processes are well-known to those skilled in the art. In this embodiment of the present invention, the copper layer 114 is formed by first forming a thick layer of copper followed by a CMP process to remove the excess copper.

The subsequent process acts are main features and key aspects of the present invention. The partial integrated circuit device 100 can then be cleaned utilizing a post CMP cleaning process at 228 (FIG. 2B) with a final BTA-last rinse prior to the IPA drying process. All of the process acts in 228 can be processed sequentially in the same equipment. The exposed copper layer 114 (FIG. 1) effectively becomes lightly carbon doped during a subsequent thermal ramp-up 230 (FIG. 2B) to 350C prior to SiCN deposition and further back end processing at 232. The carbon doping improves the SICN to Cu interface which results in improved EM and lower Hillock levels. After the back end processing at 232 is complete the process ends. Alternate films other than SiCN can be used comprising SiC:H, SiN, SiCO, amorphous-C., P-TMS SiO2 and the like.

Those skilled in the art, after reading the entirety of the present application, will understand that the methods of the present invention may be employed to form conductive interconnections at any level of an integrated circuit device using a variety of techniques, such as single or dual damascene integration techniques.

Although the invention has been shown and described with respect to one or more implementations, equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

We claim:

1. A method for forming a single damascene and/or dual damascene interconnect structure, comprising:
performing front end processing;
depositing copper;
annealing the copper;
performing CMP planarization;
performing a post copper CMP clean process,
performing a BTA rinse;
performing IPA drying process;
performing doping during thermal ramp up; and
performing remaining back end processing.

2. The method of claim 1, wherein the front end processing comprises:
forming lower layer dielectric over a semiconductor substrate;
forming etch stop layer over lower layer dielectric;
forming an upper layer dielectric over the etch stop layer;
forming a first photoresist layer over the upper layer dielectric;
forming and patterning the first photoresist layer to form a hole pattern mask;
etching hole(s) and removing the first photoresist layer;
forming a bottom-anti-reflective coating (BARC) over the substrate filling holes;
forming and patterning a second photoresist later to form the trenches; and
removing the resist & exposed region of the first etch layer, forming liner film.

3. The method of claim 1, wherein the BTA rinse is approximately 20 to 150 ppm BTA.

4. The method of claim 1, wherein the copper lines exposed to the BTA are greater than 0.05 μm.

5. The method of claim 1, wherein the BTA rinse is performed after all copper CMP clean processes.

6. The method of claim 1, wherein the post copper CMP clean process is performed ex-situ.

7. The method of claim 1, wherein the thermal ramp up is performed up to a temperature of approximately 250 to 450 C .

8. The method of claim 1, wherein the BTA rinse comprises BTA and DiW.

9. The method of claim 3, wherein a time for BTA rinse is about 2 minutes to 20 minutes.

10. The method of claim 3, wherein a temperature for the BTA rinse is 20 C to 50 C .

11. The method of claim 1, wherein the BTA can be replaced by a material comprising carbon containing copper corrosion inhibitors.
